(19) United States
(12) Patent Application Publication
(10) Pub. No.: US 2012/0169202 A1
(43) Pub. Date: Jul. 5, 2012

(54) LIGHT EMITTING DIODE (LED) AND ORGANIC LIGHT EMITTING DIODE (OLED) LIGHTING SOURCES

(75) Inventors: Christopher Leslie Marquis, Hayward, CA (US); John Albert Massa, Hayward, CA (US); David Ray Goodson, Castro Valley, CA (US)

(73) Assignee: Tahoe Lighting Concept, Inc., Livermore, CA (US)

(21) Appl. No.: 13/337,597

(22) Filed: Dec. 27, 2011

Related U.S. Application Data
(60) Provisional application No. 61/427,725, filed on Dec. 28, 2010.

(51) Int. Cl. H05K 7/20; F28F 7/00

(52) U.S. Cl. 313/46; 165/185

(57) ABSTRACT

A heat sink structure formed out of mechanisms which may include petals and stems, and which may be characterized by configurations which include rosettes and umbels. Each heat sink structure being generally comprised of multiple petals and one or more stems which are capable of interlocking with each other through use of various mechanical connector elements, which may include fin, claw and ball features. Each petal typically having a plurality of fins, claws and balls, intended to create hinge-like properties for maximizing the number and types of heat sinks which may be expressed. Advantageously, a plurality of expandable, connectable and adjustable heat sinks may be formed to optimize heat dispersion and allow for a plurality of lighting sources to be accommodated as desired.

### CROSS REFERENCE TO RELATED APPLICATIONS

The present application claims priority to U.S. Provisional Application No. 61/427,725, filed on Dec. 28, 2010, for “Light Emitting Diode (LED) and Organic Light Emitting Diode (OLED) Lighting Sources,” which is hereby incorporated by reference.

### FIELD OF INVENTION

The application relates generally to design and construction of LED and OLED lighting sources and more particularly to construction of novel and improved components of heat sinks that simplifies their assembly into a plurality of structures to accommodate LED and OLED illumination.

### BACKGROUND

The successful design and construction of LED and OLED lighting sources in a diverse field has been difficult due to the fact that their design requires the proper interplay of multiple variables, such as heat dissipation, amount and direction of illumination and physical size. As an example, U.S. Pat. No. 7,997,768 discloses extruded heat sink elements; however the heat sinks are not arrayed in multiple directions, nor does their design render them capable of being arrayed in such a fashion, let alone in 360 degrees of directional space. U.S. patent application Ser. No. 12/566,850 uses multiple removable layers of heat sinks; however these removable layers are not matched singularly to each element of the overall structure of the device.

The present invention resolves the problems of the above referenced applications. Once the petal is designed to optimally satisfy the LED and/or OLED mounting and heat dissipation requirements, it may be matched singularly and interlocked with other petals in geometrical fashion to direct heat and illumination in any desired amount and/or direction. This simplicity and diversity of design and arrangement facilitates the fabrication and performance requirements of various configurations of the invention needed to support maximum life-span and energy efficiency of any given LED or OLED lighting device intended to satisfy a desired purpose.

### SUMMARY OF THE INVENTION

The present invention is related to a novel design of a heat sink, referred to as a “PETAL”. It has a novel structure principally defined by heat dissipation and connection features that enable the petal to perform its function either as a stand-alone structure or as part of a number of petals interlocked with one another. In an embodiment, the petal may use elongated fins for heat dissipation and a ball and claw mechanism for coupling multiple petals. The advantageous and novel design of the petal allows assembly of a plurality of lighting structures, any one of which may be freely oriented, arranged or directed in any directional fashion throughout a full 360 degrees of three-dimensional space.

Due to its novel design the petal may be used as a mounting structure for an illumination producing device while simultaneously being capable of dissipating heat produced by that or other illumination producing devices, which will generally be LEDs or OLEDs. The petal may additionally function as a mounting structure for a lens which can be placed to cover the LED and as a mounting structure for electrical connections between an LED and a power source.

A particularly preferred embodiment of the invention represents a heat sink petal, comprised of a petal body with an upper and lower side, a plurality of fins extending from the upper and/or lower side of the petal and a mounting surface on the lower side of the petal to accommodate attachment of an illumination producing device. The petal can be interlocked with one or more petals and/or with other devices through mechanical connector features existing on and about the sides of any petal. In an embodiment, a ball or cylinder structure can be formed on one side of the petal and a claw structure can be formed on an opposite side of the petal. The petal can also be attached to a stem structure through stem connector features extending from the upper side of the petal body.

In an embodiment the first edge of the petal body and the ball connector axis define a first plane and a second edge of the petal body and the claw connector axis define a second plane. The intersection of the first plane and the second plane form an angle which can vary between about 80 degrees and 130 degrees. This geometric feature can allow two or more petals to be coupled together to form larger annular or linear structures.

To particular advantage, the petal is designed in a fashion which enables groups of petals to be linked together by their respective connector features to form “ROSETTES,” where the mounting surfaces of each petal face outward from the central heat sink. If LEDs are mounted on the petal mounting surfaces the rosette will be capable of dispersing light outright from the mounting surfaces. Multiple rosettes may be interlocked in a variety of geometric shapes to attain a desired amount of illumination and heat dispersion capability. In an embodiment, the connector features can include claws which can be an elongated tubular structure having an open side and balls which can be an elongated cylindrical structure. The ball feature may fit tightly within the claw feature and may allow for hinge-like rotation between the connected petals.

Petals and rosettes can be connected to each other and to stem features through various means including their respective claw and ball features, stem connector features, other mechanical connector features or adhesion agents such as thermal epoxy to form more complex structures which may exist as groups of rosettes or as various polygonal shapes including equilateral convex polygons; “UMBELS.”

For a more complete understanding of all features and possible embodiments of the invention, reference should be made to the following detailed description of preferred embodiments, which are each and collectively intended to illustrate, not limit, the invention.

### BRIEF DESCRIPTION OF THE DRAWINGS

FIG. 1 is a cross-sectional plan view of three linked petals, as described in the first embodiment.

FIG. 2 is an elevational isometric view of three linked petals, as described in the first embodiment.

FIG. 3 is a cross-sectional topside-down plan view of a petal, as described in the first embodiment.

FIG. 4 is an elevational topside-down isometric view of a petal, as described in the first embodiment.

FIG. 5 is a cross-sectional topside-down plan view of a petal, illustrating its relevant angles of configuration, as described in the first embodiment.

FIG. 6 is a cross-sectional plan view of two petals, as included in the first embodiment, illustrating how the petals link together.

FIG. 7 is a cross-sectional plan view of three petals, as included in the first embodiment, illustrating how the petals link together.

FIG. 8 is a cross-sectional plan view of a stem, as included in the four described embodiments.

FIG. 9 is an elevational isometric view of a stem, as included in the four described embodiments.

FIG. 10 is a cross-sectional plan view of a rosette, as described in the first embodiment.

FIG. 11 is an elevational topside-down isometric view of the mounting surface of a petal, as included in the four described embodiments.

FIG. 12 is a cross-sectional plan view of four linked petals, as described in the second embodiment.

FIG. 13 is an elevational isometric view of four linked petals, as described in the second embodiment.

FIG. 14 is a cross-sectional topside-down plan view of a petal, described in the second embodiment.

FIG. 15 is an elevational topside down isometric view of a petal, as described in the second embodiment.

FIG. 16 is a cross-sectional topside down plan view of a petal, illustrating its relevant angles of configuration, as included in the second embodiment.

FIG. 17 is a cross-sectional plan view of four linked petals, as described in the second embodiment, illustrating how the petals link together.

FIG. 18 is a cross-sectional plan view of a rosette, as described in the second embodiment.

FIG. 19 is a cross-sectional plan view of three petals linked together, as described in the third embodiment.

FIG. 20 is an elevational isometric view of three petals linked together, as described in the third embodiment.

FIG. 21 is a cross-sectional topside-down plan view of a petal, as described in the third embodiment.

FIG. 22 is an elevational topside down isometric view of a petal, as described in the third embodiment.

FIG. 23 is a cross-sectional topside-down plan view of a petal, illustrating its relevant angles of configuration, as described in the third embodiment.

FIG. 24 is a cross-sectional plan view of three petals linked together, as described in the third embodiment, illustrating how the petals link together.

FIG. 25 is a cross-sectional plan view of a rosette, as described in the third embodiment.

FIG. 26 is an elevational isometric view of an umbel with petals linked singularly to each stem section, as described in the fourth embodiment.

FIG. 27 is an elevational isometric view of an umbel with petals linked to stem sections both singularly and in groups, as described in the fourth embodiment.

FIG. 28 is an elevational isometric view of multiple petals linked at 15 degree increments around a section of stem, as described in the fourth embodiment.

FIG. 29 is a cross-sectional plan view of multiple petals linked at 15 degree increments around a section of stem, as described in the fourth embodiment.

FIG. 30 illustrates a variety of other expressions of heat sink structures which may be achieved by the described invention.

### DETAILED DESCRIPTION

### First Preferred Embodiment

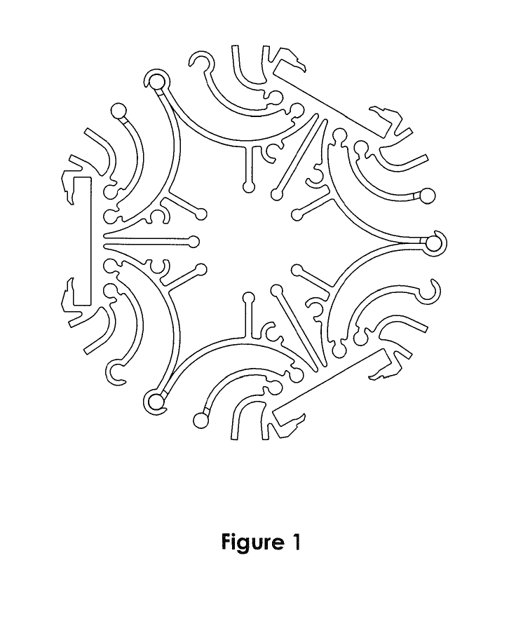

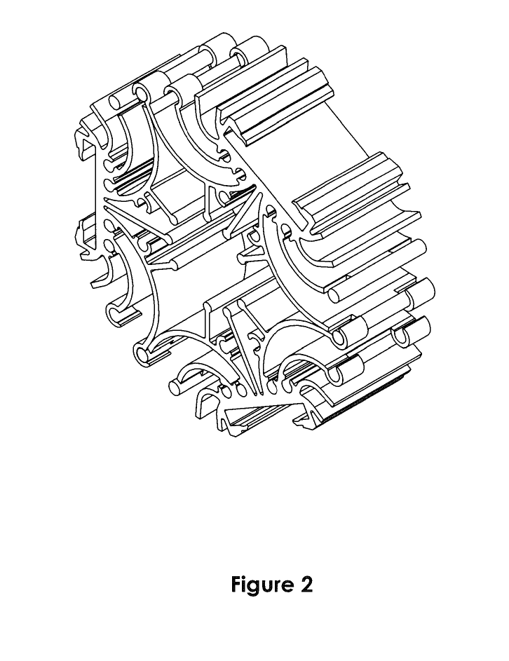

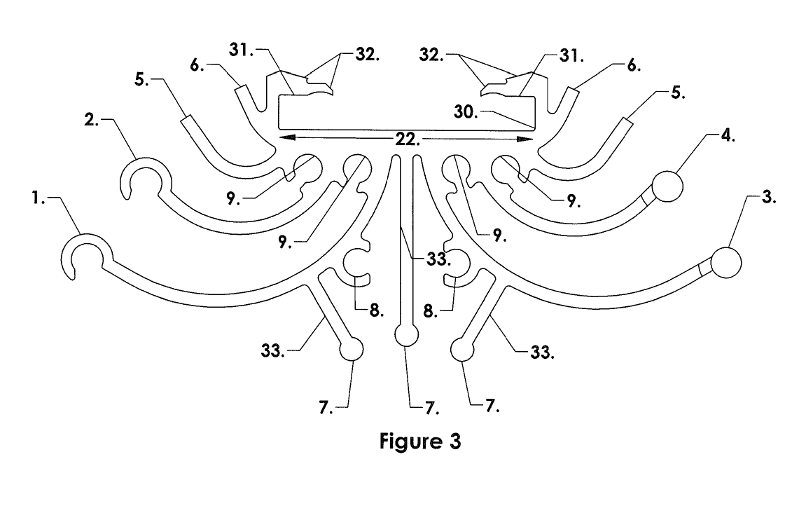

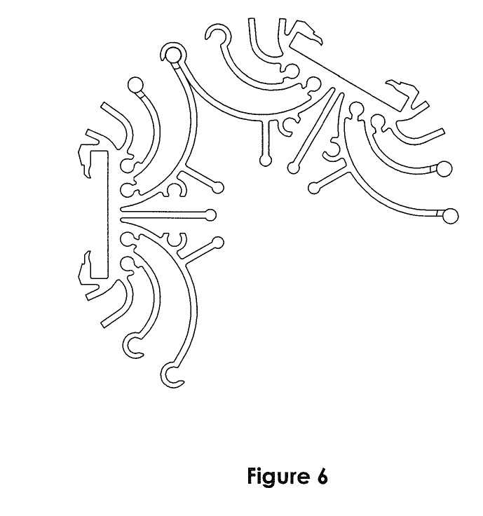

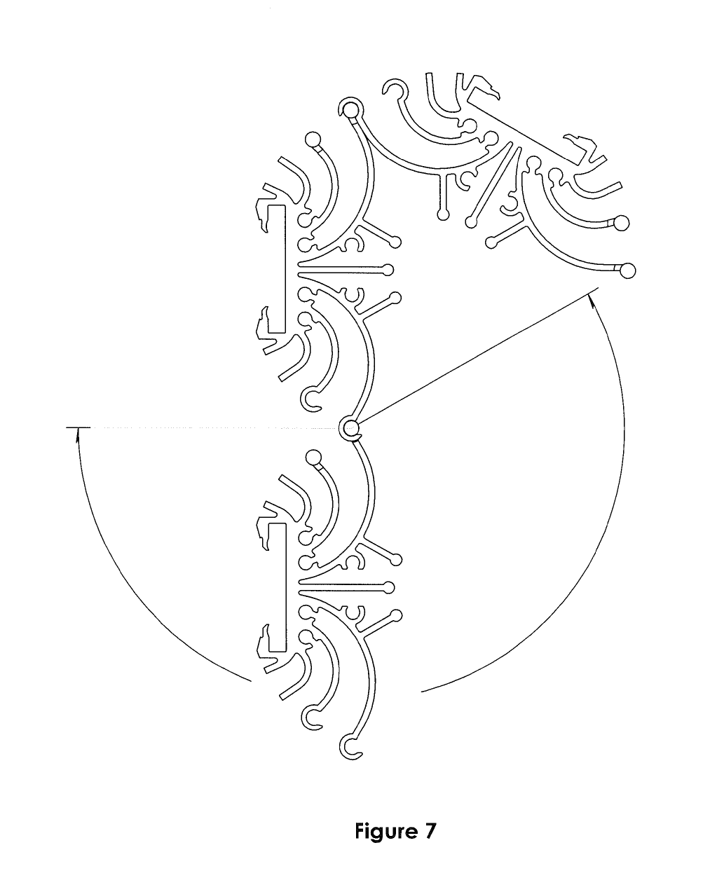

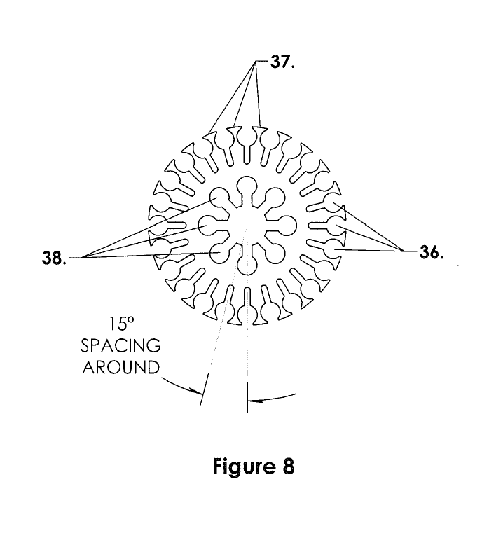

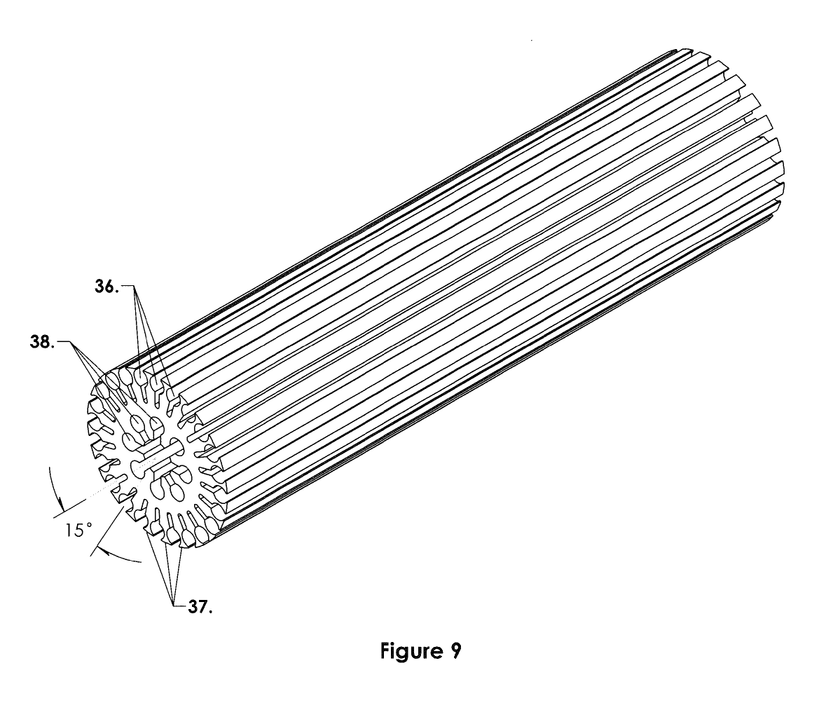

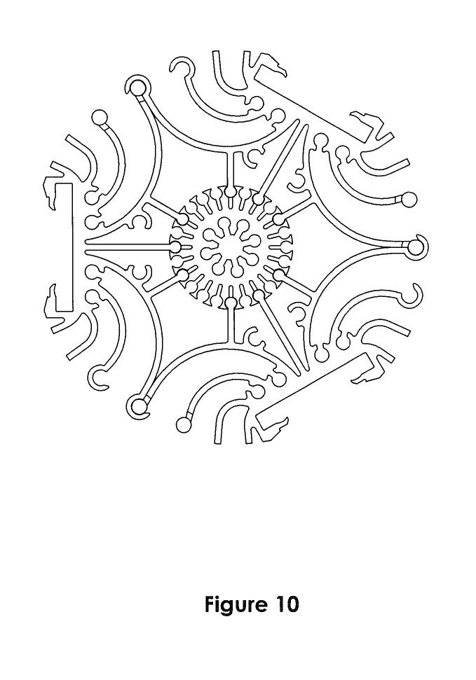

Referring now to the drawings, a first embodiment of the invention is illustrated in FIGS. 1-11. A first embodiment of the invention may be expressed by three linked petals, as depicted in FIGS. 1 and 2. Each petal, as depicted in FIGS. 3, 4 and 5, may be linked to each other by connective mechanical features at various points including the respective left and right ends of each, as depicted in FIGS. 6 and 7. The left and right ends of each petal can be generally defined as one or more of a plurality of fins; in this embodiment typically the uppermost fin on each side of each petal serves as the primary connective element between the linked petals, as depicted in FIGS. 6 and 7. As depicted in FIG. 3, the ends of the two left uppermost fins on each petal can have mechanical connector features which may be claws (1) (2), while the ends of the two right uppermost fins can have mechanical connector features which may be balls (3) (4). The three linked petals may be fixed to each other through the use of their respective mechanical connector features, and may be fixed to and around a stem, as depicted in FIGS. 8 and 9, by additional elongated connector features located on and about each petal (7). The petals and stern linked in this fashion may collectively form a heat sink structure which can be called a rosette, as depicted in FIG. 10.

Each heat sink petal may be fashioned from aluminum or any other suitable material by means of direct hot extrusion or another suitable process. The heat sink petals may then be processed by coating each with an electroless nickel finish or another suitable substance. All of the heat sink petals in a heat sink structure, a rosette or otherwise, may be fashioned in a substantially identical manner and may have a substantially identical form.

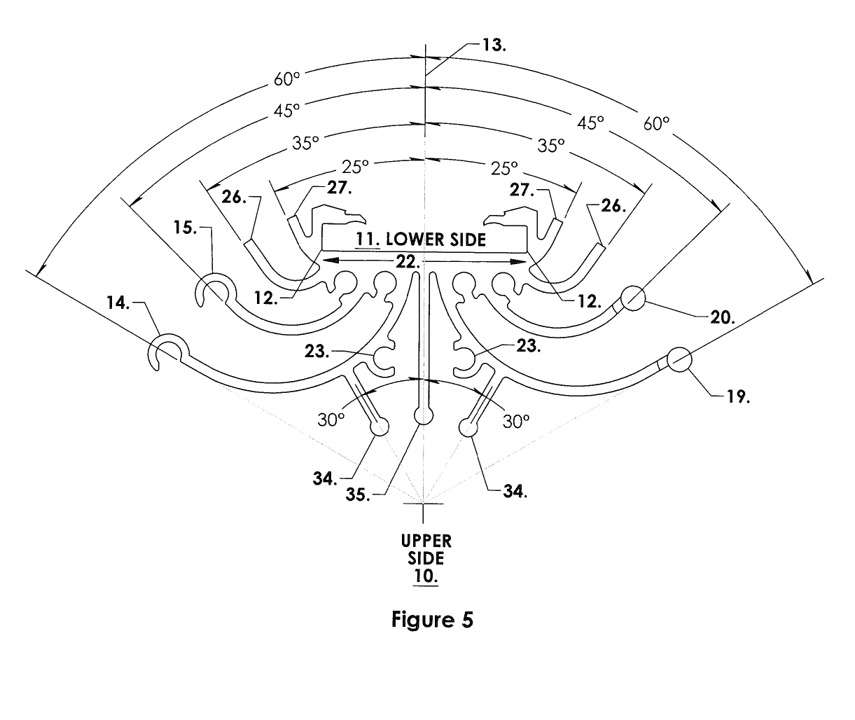

In the illustrated embodiment, as depicted in FIG. 5, each heat sink petal is comprised of an upper side (10) and a lower side (11) and may have eight fins each extending in an arching fashion from various evenly spaced points on and about its upper side and widthwise edges (12); each fin situated in angular relation to the center axis line of the petal body (13).

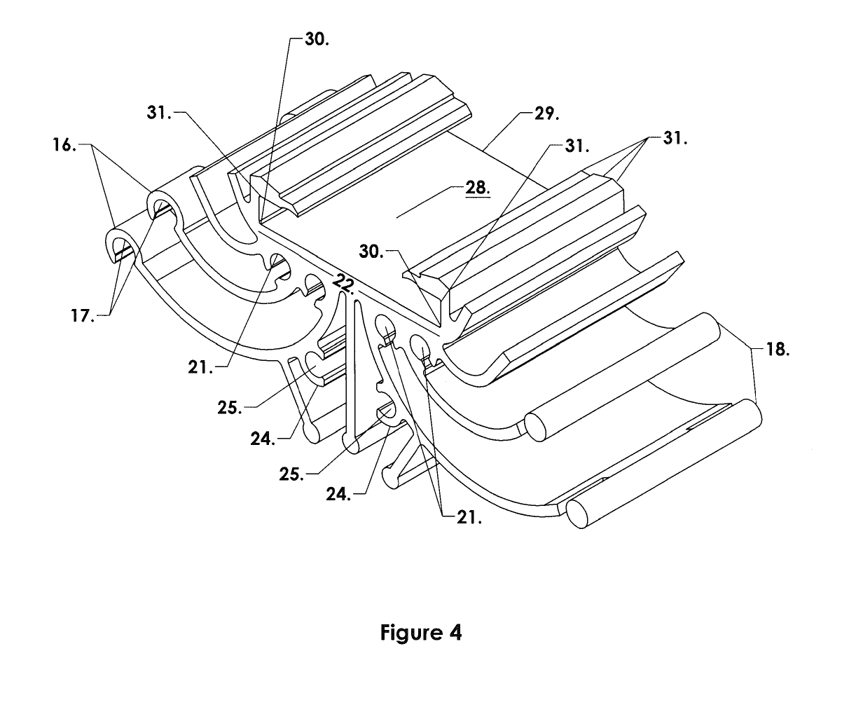

In the illustrated embodiment, four evenly spaced fins extend on and about the upper side of the petal body on each side of the center axis line of the petal body. The two uppermost fins on the left side of the petal may have claw connector features at their ends which respectively rest at approximately 60 degrees (14) and 45 degrees (15) from the center axis line of the petal body, as depicted in FIG. 5. Each claw connector feature, as depicted in FIG. 4, generally has an elongated cylindrically contoured wall section with portions thereof extending over an arc of greater than 180 degrees (16) and has an open side with portions thereof extending over an arc of less than 180 degrees (17). As depicted in FIG. 5, the two uppermost fins on the right side of the petal may have ball connector features at their ends which respectively rest at approximately 60 degrees (19) and 45 degrees (20) from the center axis line of the petal body. A ball connector feature, as depicted in FIG. 4, generally exists in an elongated cylindrical fashion (18).

The points at which each of the three uppermost fins on the left and right sides of the petal meet the base-surface of the petal body (22), as depicted in FIGS. 3, 4 and 5, can each be defined by additional claw features (9). In the illustrated embodiment there are four base-surface claw features, each having an open side with portions thereof extending over an arc of less than 180 degrees (21), allowing for additional connector functionality, and/or pass-through functionality and increased surface area for more effective heat dispersion.

As depicted in FIGS. 3, 4 and 5, the uppermost fins on the left and right sides of the center axis line of the petal body can each have an additional claw feature which protrudes from their inward facing sides (8). Each of these additional claws can be situated (23) approximately 20 degrees from the central axis line of the petal body, and may each be shaped in a C-like fashion having an elongated cylindrically contoured wall section with portions thereof extending over an arc of greater than 180 degrees (24) and having an open side with portions thereof extending over an arc of less than 180 degrees (25). Each additional claw feature can allow for additional connector functionality, and/or pass through functionality and increased surface area for more effective heat dispersion.

As depicted in FIGS. 3 and 5, the third uppermost or second lowermost fins on the left and right sides of the petal (5) can each arc in a primarily downward fashion and terminate (26) at approximately 35 degrees from the center axis line of the petal body.

As depicted in FIGS. 3 and 5, the lowermost fin (6) originating from each side edge (12) of the base-surface of the petal body (22) may extend in a short downward directed arc, each having its point of termination (27) at approximately 25 degrees from the center axis line of the petal body.

In the illustrated embodiment the base-surface of the petal body has an upper and a lower side with the contour of its upper side being generally defined by the fin features as discussed above and the lower side of the petal body existing generally as a mounting surface face (28), as depicted in FIGS. 3 and 4, having features intended to accommodate the affixation of a heat producing device, which is typically a light emitting diode (LED), and/or the affixation of a lens.

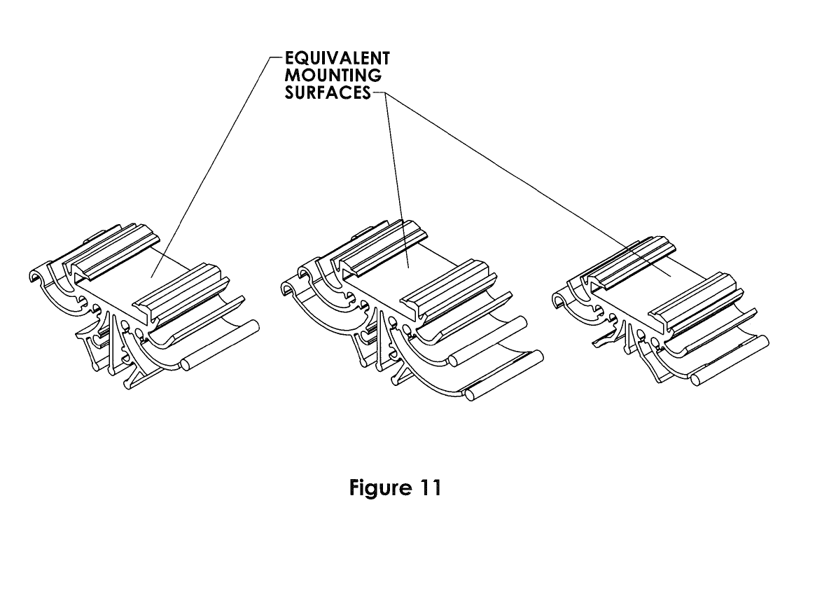

The lower side of the petal body can be comprised primarily by a surface intended for mounting capabilities; the mounting surface of each petal in the various illustrated embodiments may be substantially identical to each other; as depicted in FIG. 11.

As depicted in FIG. 4, the mounting surface may be defined generally in a rectangular fashion by lengthwise edges (29), and widthwise by elongated walls at either end (30). The widthwise walls extend downwards and then fold inwards toward each other (31), each at approximately a 90 degree angle and extend under and parallel to the mounting surface for a short distance, being tapered down in a cut-away step like fashion (32) until each terminates. The intent of each folded-under wall can be the creation of a feature allowing connective elements of a heat producing device and/or a lens to be snapped into place and sandwiched together. The face of the mounting surface (28) may be fashioned to include threading or shallow grooving features intended to accommodate fastening or hinging agents or other means of affixation such as thermal epoxy.

The first, second and third petals, which may be substantially identical to one another, can be coupled to each other, as depicted in FIGS. 6 and 7, by their respective mechanical connector features, and fastened to and around a stem, as depicted in FIGS. 8 and 9, by the elongated stem connectors of each petal (33), which number three per petal in this embodiment and can each have an elongated cylindrical ball at each of their ends (7), as depicted in FIGS. 3 and 4.

As depicted in FIG. 5, the left and right stem connectors (34) each extend at an angle of approximately 30 degrees from the center axis line of the petal body, and the central stem connector (35) extends along the center axis line itself.

The stem, as depicted in FIGS. 8 and 9, generally exists as an elongated rod fashioned by means of direct hot extrusion or another suitable process. The stem can be fashioned from aluminum or any other suitable material. The stem can also be treated with a coating such as an electroless nickel finish or another suitable substance.

The stem connector features of each petal can be coupled to elongated cylindrically contoured claw features extending the length of the stem (36) and each having an elongated cylindrically contoured wall section with portions thereof extending over an arc of greater than 180 degrees and an open side with portions thereof extending over an arc of less than 180 degrees. Each stem claw feature may be arranged in evenly and closely spaced intervals, approximately 15 degrees each (37), around the outer surface area of the stem, such that the left inner wall curve of any particular claw feature may, on its other side, define the right inner wall curve of the claw feature immediately to the left.

The center interior axis-line of the stem, which may generally run the length of the stem, can be comprised of an open space (38), which may be generally defined by a plurality of elongated cylindrically contoured inward facing claw features (39), each having an elongated cylindrically contoured wall section with portions thereof extending over an arc of greater than 180 degrees and an open side with portions thereof extending over an arc of less than 180 degrees. Each inward facing claw feature can run the length of the interior of the stem and be spaced at close and even intervals such that the left inner wall curve of any particular claw feature may, on its opposite side, define the right inner wall curve of the claw feature immediately to the left.

Cumulatively, the inward facing claw features can give the open space at the center of the stem the appearance of a snowflake when the stem or the entire rosette is viewed in a cross-sectional plan perspective as, depicted in FIG. 10. An intended purpose of the open space can be to provide additional surface area and a pass through feature for facilitating more effective heat dispersion.

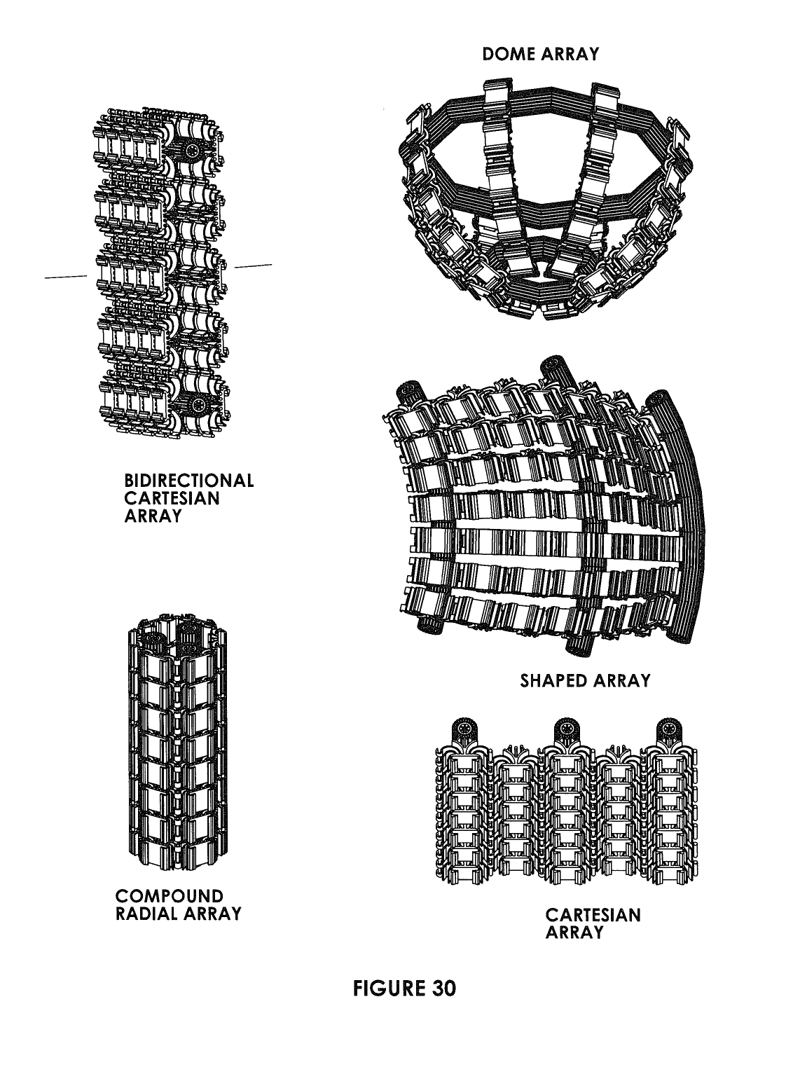

The first, second and third petals, and the stem, may be coupled with each other in the manner described above to form a desired rosette heat sink, as depicted in FIG. 10. Any rosette heat sink may be further coupled and affixed to additional similar rosette heat sinks utilizing additional stems and/or the additional mechanical connector features of any of the petals from which the connected rosettes are comprised, as depicted in FIG. 30.

A number of additional embodiments similar to the one described above may be achieved by altering the configuration and/or design of the petals. For example, such changes may include varying the number of fins defining the topside contours of a number of petals to be linked together to form a given rosette, as well as by altering the angles at which such fins arc and the lengths to which they extend. Different rosettes may be formed by linking two or more petals to each other and/or around and to a stem. One or more rosettes may also be linked to each other by affixing them directly to one another and/or to additional stems through the use of additional mechanical connector features, including claw and ball features, existing on the respective petals. Generally, each and every coupling of claw and ball features is capable of acting in a hinge-like fashion, which may increase the variety of petal and rosette structures that can be arranged and included in the invention. Examples of this variety are illustrated by FIG. 30.

Each possible combination of different petal types, different rosettes, and different stem configurations may, depending on its basic components, be considered a distinct embodiment of the invention.

### Second Preferred Embodiment

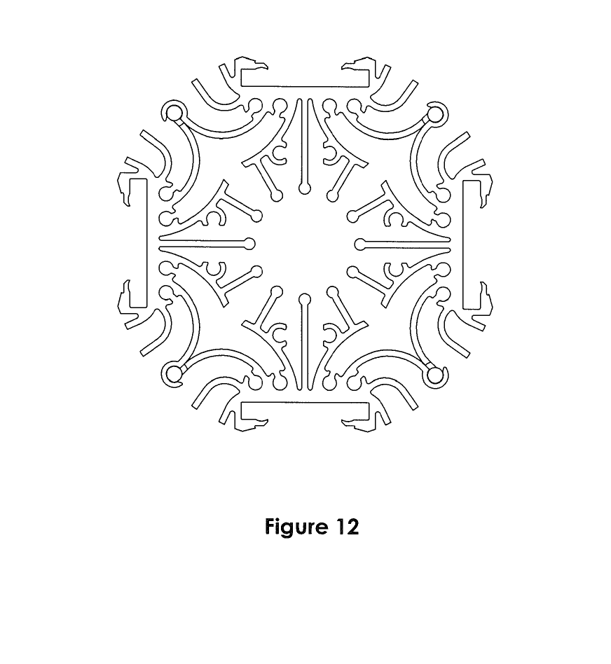

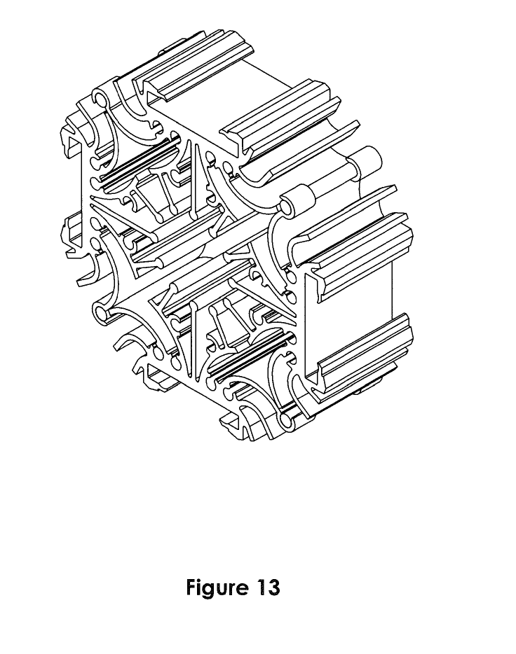

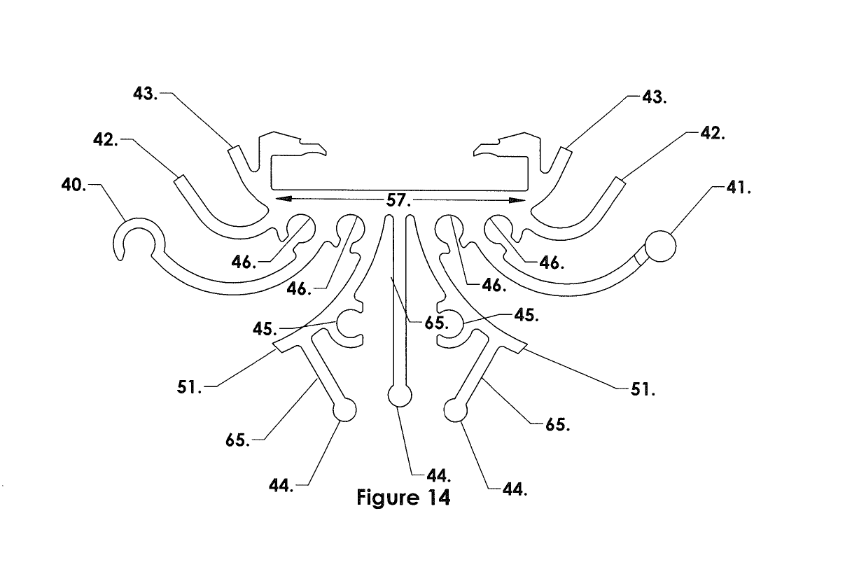

Referring to FIGS. 12-18, another preferred embodiment of a heat sink petal is illustrated in FIGS. 14, 15 and 16. A plurality of this petal design is shown linked together, as depicted in FIGS. 12 and 13. The illustrated embodiment primarily describes a heat sink petal and omits description of the mounting surface of the described petal and of the stem included in the embodiment because these features can be substantially identical to those described in the first embodiment.

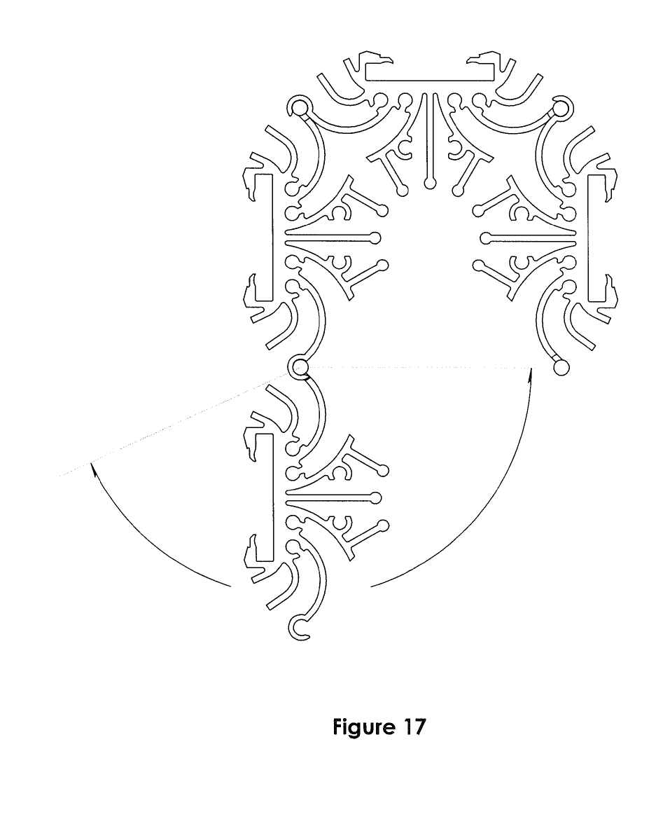

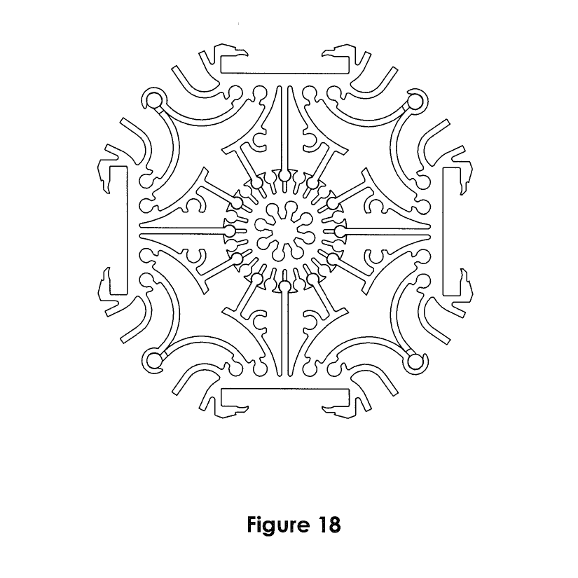

A second embodiment may be expressed by four linked petals, where each petal may be linked to each other by connective mechanical features at various points including the respective left and right ends of each, as depicted in FIG. 17. The left and right ends of each petal can be generally defined as one or more of a plurality of fins; in this embodiment typically the second-uppermost fin on each side of each petal serves as the primary connective element between the linked petals, as depicted in FIG. 17. The end of the left second uppermost fin can have a mechanical connector feature which may be a claw (40), while the end of the right second uppermost fin can have a mechanical connector feature which may be a ball (41). The four linked petals may be fixed to each other through the use of their respective mechanical connector features, and may be fixed to and around a stem, as depicted in FIGS. 8 and 9, by additional elongated connector features located on and about each petal (44), as depicted in FIG. 14. The petals and stem linked in this fashion may collectively form a heat sink structure which can be called a rosette, as depicted in FIG. 18.

Each heat sink petal, as depicted in FIGS. 14, 15 and 16, may be fashioned from aluminum or any other suitable material by means of direct hot extrusion or another suitable process. The heat sink petals may then be processed by coating each with an electroless nickel finish or another suitable substance. All of the heat sink petals in a heat sink structure, a rosette or otherwise, may be fashioned in a substantially identical manner and may have a substantially identical form.

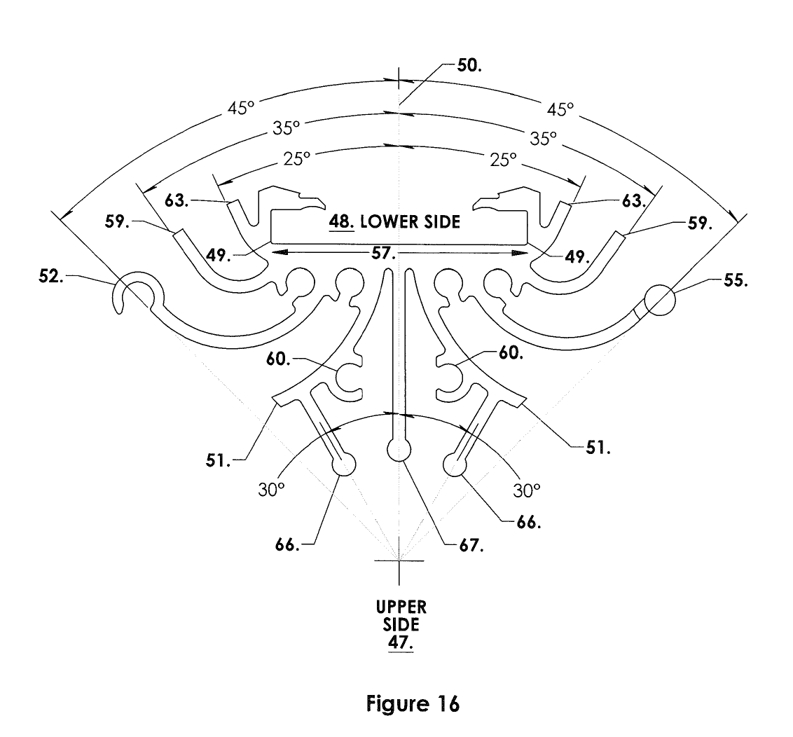

In the illustrated embodiment, each heat sink petal is comprised of an upper side (47) and a lower side (48) and may have eight fins each extending in an arching fashion from various evenly spaced points on and about its upper side and widthwise edges (49), each fin situated in angular relation to the center axis line of the petal body (50), as depicted in FIG. 16.

In the illustrated embodiment, as depicted in FIGS. 14 and 16, four evenly spaced fins extend on and about the upper side of the petal body on each side of its center axis line. The uppermost fin on each side of the petal (51) does not have any connector feature at its end, but instead may be terminated at an early point in its arc (51), as depicted in FIG. 16, approximately 35 degrees from the center axis line of the petal body.

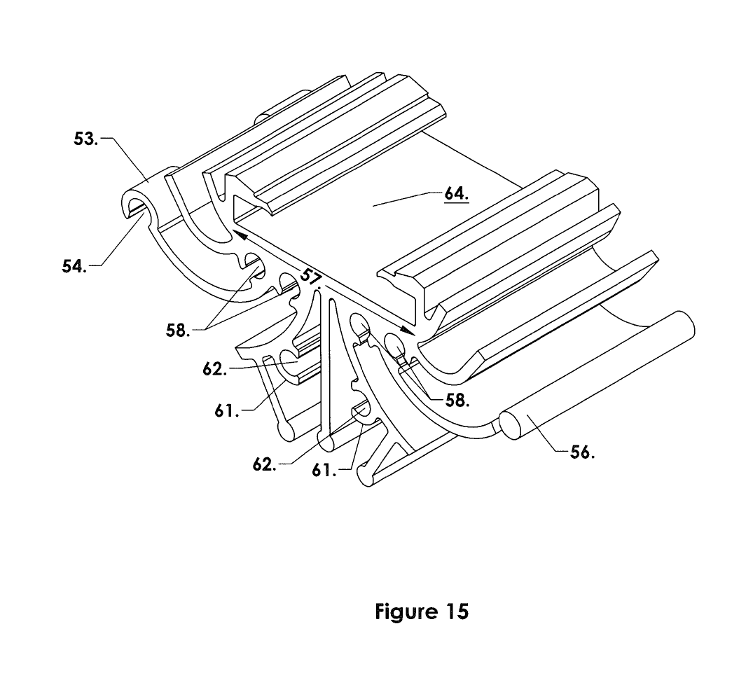

The second uppermost fin on the left side of the petal may have a claw connector feature at its end (52) which rests at approximately 45 degrees from the center axis line of the petal body, as depicted in FIG. 16. The claw connector feature, as depicted in FIG. 15, generally has an elongated cylindrically contoured wall section with portions thereof extending over an arc of greater than 180 degrees (53) and has an open side with portions thereof extending over an arc of less than 180 degrees (54). The second uppermost fin on the right side of the petal may have a ball connector feature at its end (55) which rests at approximately 45 degrees from the center axis line of the petal body, as depicted in FIG. 16. A ball connector feature, as depicted in FIG. 15, generally exists in an elongated cylindrical fashion (56).

The points at which each of the three uppermost fins on the left and right sides of the petal meet the base-surface of the petal body (57), as depicted in FIGS. 14 and 15, can each be defined by additional claw features (46). In the illustrated embodiment there are four base-surface claw features, each having an open side with portions thereof extending over an arc of less than 180 degrees (58), allowing for additional connector functionality, and/or pass-through functionality and increased surface area for more effective heat dispersion.

As depicted in FIGS. 14 and 16, the third uppermost or second lowermost fins on the left and right sides of the petal (42) can each arc in a primarily downward fashion and terminate (59) at approximately 35 degrees from the center axis line of the petal body.

As depicted in FIGS. 14, 15 and 16, the uppermost fins on the left and right sides of the center axis line of the petal body can each have an additional claw feature which protrudes from their inward facing sides (45). Each of these additional claws can be situated (60) at approximately 20 degrees from the center axis line of the petal body, and may each be shaped in a C-like fashion having an elongated cylindrically contoured wall section with portions thereof extending over an arc of greater than 180 degrees (61) and having an open side with portions thereof extending over an arc of less than 180 degrees (62). Each additional claw feature can allow for additional connector functionality, and/or pass through functionality and increased surface area for more effective heat dispersion.

As depicted in FIGS. 14 and 16, the lowermost fin (43) originating from each side edge (49) of the base-surface of the petal body (57) may extend in a short downward directed arc, each having its point of termination (63) at approximately 25 degrees from the center axis line of the petal body.

In the illustrated embodiment the base-surface of the petal body has an upper and a lower side with the contour of its upper side being generally defined by the fin features as discussed above and the lower side of the petal body existing generally as a mounting surface face (64), as depicted in FIGS. 14 and 15, having features intended to accommodate the affixation of a heat producing device, which is typically a light emitting diode (LED), and/or the affixation of a lens.

The first, second, third and fourth petals, which may be substantially identical to one another, can be coupled to each other, as depicted in FIG. 17, by their respective mechanical connector features, and fastened to and around a stem, as depicted in FIGS. 8 and 9, by the elongated stem connectors of each petal (65), which number three per petal in this embodiment and can each have an elongated cylindrical ball at each of their ends (44), as depicted in FIGS. 14 and 15.

As depicted in FIG. 16, the left and right stem connectors (66) each extend at an angle of approximately 30 degrees from the center axis line of the petal body, and the central stem connector (67) extends along the center axis line itself.

The first, second, third and fourth petals, and the stem, may be coupled with each other in the manner described above to form a desired rosette heat sink, as depicted in FIG. 18. Any rosette heat sink may be further coupled and affixed to additional similar rosette heat sinks utilizing additional stems and/or the additional mechanical connector features of any of the petals from which the connected rosettes are comprised, as depicted in FIG. 30.

### Third Preferred Embodiment

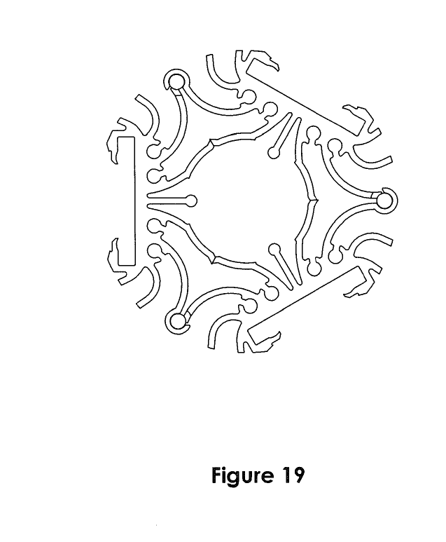

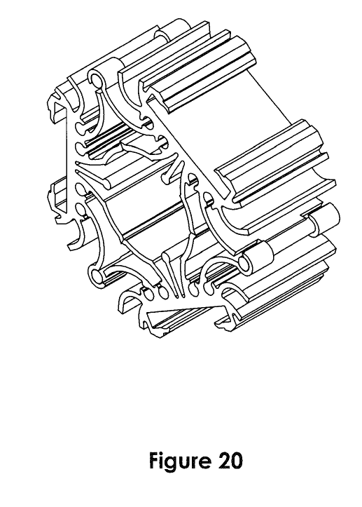

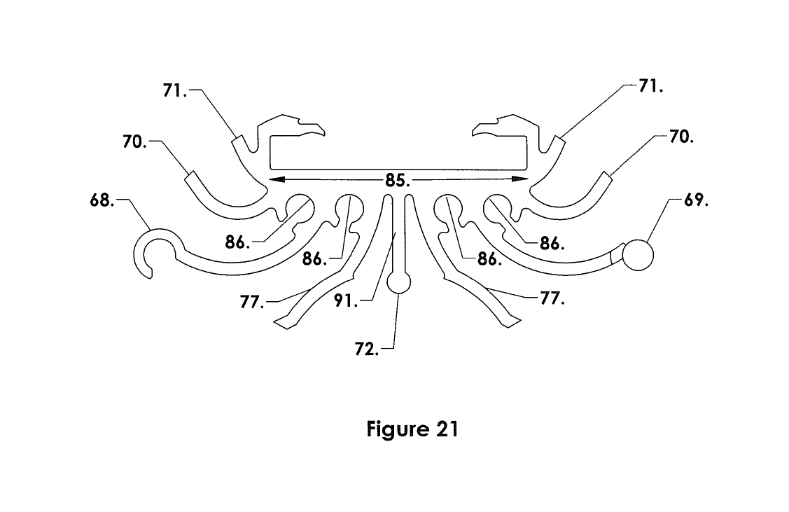

Referring to FIGS. 19-25, another preferred embodiment of a heat sink petal is illustrated in FIGS. 21, 22 and 23. A plurality of this petal design is shown linked together, as depicted in FIGS. 19 and 20. The illustrated embodiment primarily describes a heat sink petal and omits description of the mounting surface of the described petal and of the stem included in the embodiment because these features can be substantially identical to those described in the first embodiment.

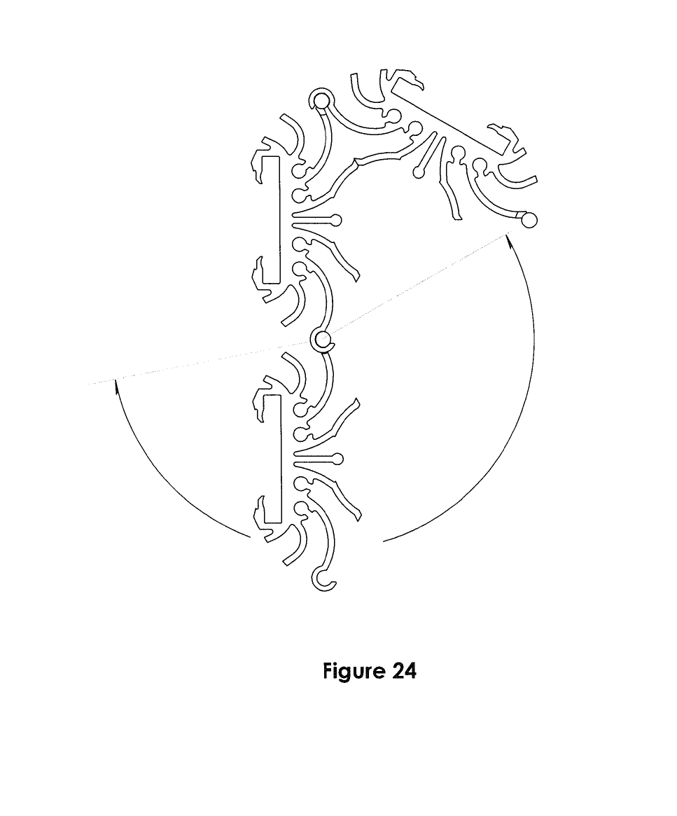

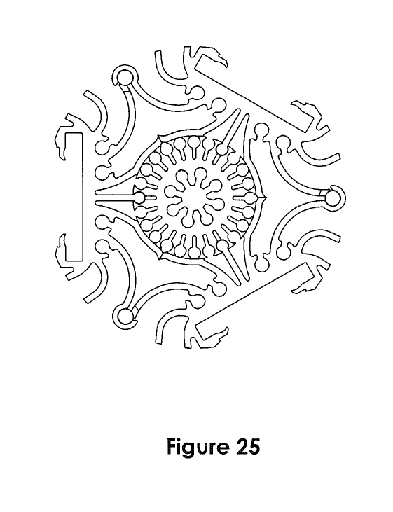

A third embodiment may be expressed by three linked petals, where each petal may be linked to each other by connective mechanical features at various points including the respective left and right ends of each, as depicted in FIG. 24. The left and right ends of each petal can be generally defined as one or more of a plurality of fins; in this embodiment typically the second-uppermost fin on each side of each petal serves as the primary connective element between the linked petals, as depicted in FIG. 24. The end of the left second uppermost fin can have a mechanical connector feature which may be a claw (68), while the end of the right second uppermost fin can have a mechanical connector feature which may be a ball (69). The three linked petals may be fixed to each other through the use of their respective mechanical connector features, and may be fixed to and around a stem, as depicted in FIGS. 8 and 9, by additional elongated connector features located on and about each petal (72). The petals and stem linked in this fashion may collectively form a heat sink structure which can be called a rosette, as depicted in FIG. 25. Each heat sink petal, as depicted in FIGS. 21, 22 and 23, may be fashioned from aluminum or any other suitable material by means of direct hot extrusion or another suitable process. The heat sink petals may then be processed by coating each with an electroless nickel finish or another suitable substance. All of the heat sink petals in a heat sink structure, a rosette or otherwise, may be fashioned in a substantially identical manner and may have a substantially identical form.

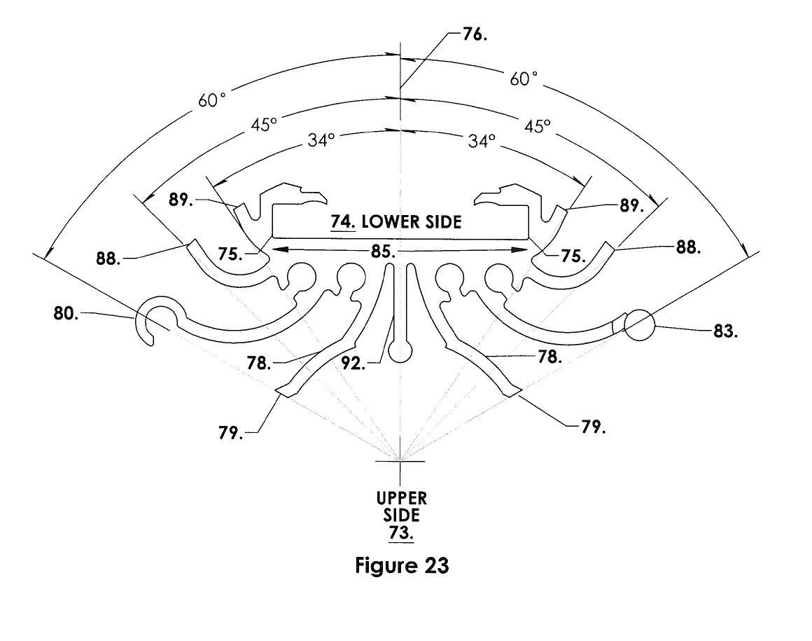

In the illustrated embodiment, each heat sink petal is comprised of an upper side (73) and a lower side (74) and may have eight fins each extending in an arching fashion from various evenly spaced points on and about its upper side and widthwise edges (75), each fin situated in angular relation to the center axis line of the petal body (76), as depicted in FIG. 23.

In the illustrated embodiment four evenly spaced fins extend on and about the upper side of the petal body on each side of its center axis line. The uppermost fin on each side of the petal (77) does not have any connector feature at its end, but instead may be slightly bent at an early point in its arc (78), as depicted in FIG. 23, and then extend a short distance to its point of termination (79), approximately 60 degrees from the center axis line of the petal body. An intent of the bent feature of the uppermost fin may be allowing a section of the fin to rest flush against the outer surface area of the stem to act as an additional connector feature.

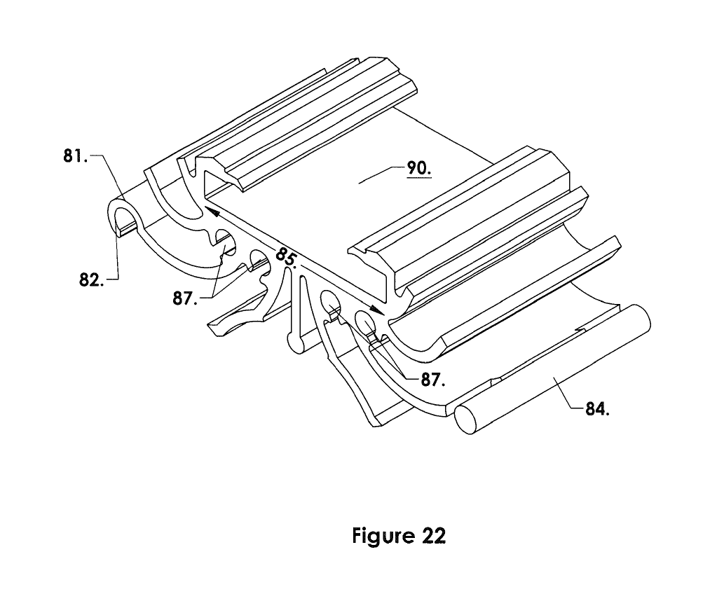

The second uppermost fin on the left side of the petal may have a claw connector feature at its end (80) which rests at approximately 60 degrees from the center axis line of the petal body, as depicted in FIG. 23. The claw connector feature, as depicted in FIG. 22, generally has an elongated cylindrically contoured wall section with portions thereof extending over an arc of greater than 180 degrees (81) and has an open side with portions thereof extending over an arc of less than 180 degrees (82). The second uppermost fin on the right side of the petal may have a ball connector feature at its end (83) which rests at approximately 60 degrees from the center axis line of the petal body, as depicted in FIG. 23. A ball connector feature, as depicted in FIG. 22, generally exists in an elongated cylindrical fashion (84).

The points at which each of the three uppermost fins on the left and right sides of the petal meet the base-surface of the petal body (85), as depicted in FIGS. 21, 22 and 23, can each be defined by additional claw features (86). In the illustrated embodiment there are four base-surface claw features, each having an open side with portions thereof extending over an arc of less than 180 degrees (87), allowing for additional connector functionality, and/or pass-through functionality and increased surface area for more effective heat dispersion.

As depicted in FIGS. 21 and 23, the third uppermost or second lowermost fins on the left and right sides of the petal (70) can each arc in a primarily downward fashion and terminate (88) at approximately 45 degrees from the center axis line of the petal body.

As depicted in FIGS. 21 and 23, the lowermost fin (71) originating from each side edge (75) of the base-surface of the petal body (85) may extend in a short downward directed arc, each having its point of termination (89) at approximately 34 degrees from the center axis line of the petal body.

In the illustrated embodiment the base-surface of the petal body has an upper and a lower side with the contour of its upper side being generally defined by the fin features as discussed above and the lower side of the petal body existing generally as a mounting surface face (90), as depicted in FIGS. 21 and 22, having features intended to accommodate the affixation of a heat producing device, which is typically a light emitting diode (LED), and/or the affixation of a lens.

The first, second and third petals, which may be substantially identical to one another, can be coupled to each other, as depicted in FIG. 24, by their respective mechanical connector features, and fastened to and around a stem, as depicted in FIGS. 8 and 9, by the elongated stem connectors of each petal (91), which number one per petal in this embodiment and can each have an elongated cylindrical ball at each of their ends (72), as depicted in FIGS. 21 and 22. As depicted in FIG. 23, the central stem connector (92) extends along the center axis line itself.

The first, second and third petals, and the stem, may be coupled with each other in the manner described above to form a desired rosette heat sink, as depicted in FIG. 25. Any rosette heat sink may be further coupled and affixed to additional similar rosette heat sinks utilizing additional stems and/or the additional mechanical connector features of any of the petals from which the connected rosettes are comprised, as depicted in FIG. 30.

### Fourth Preferred Embodiment

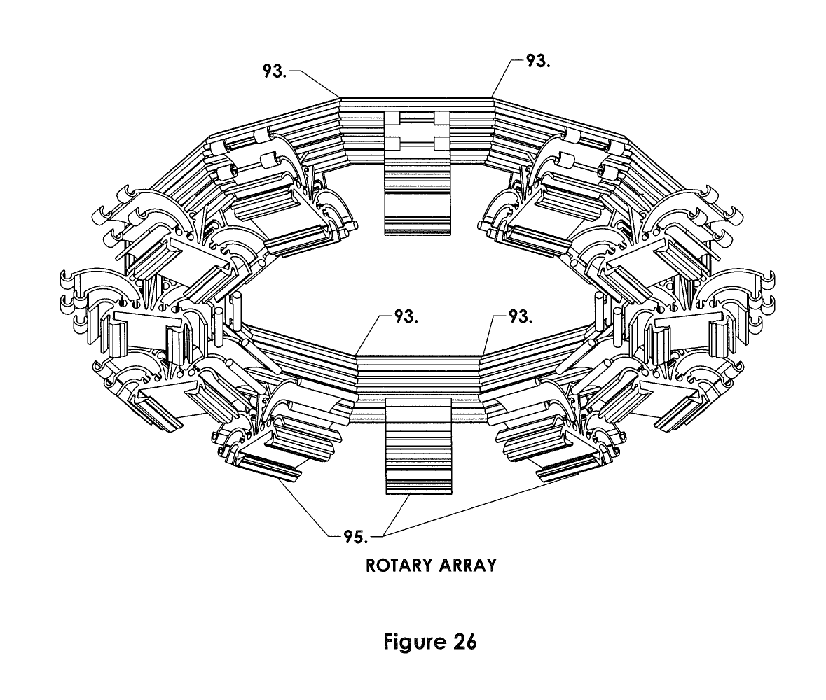

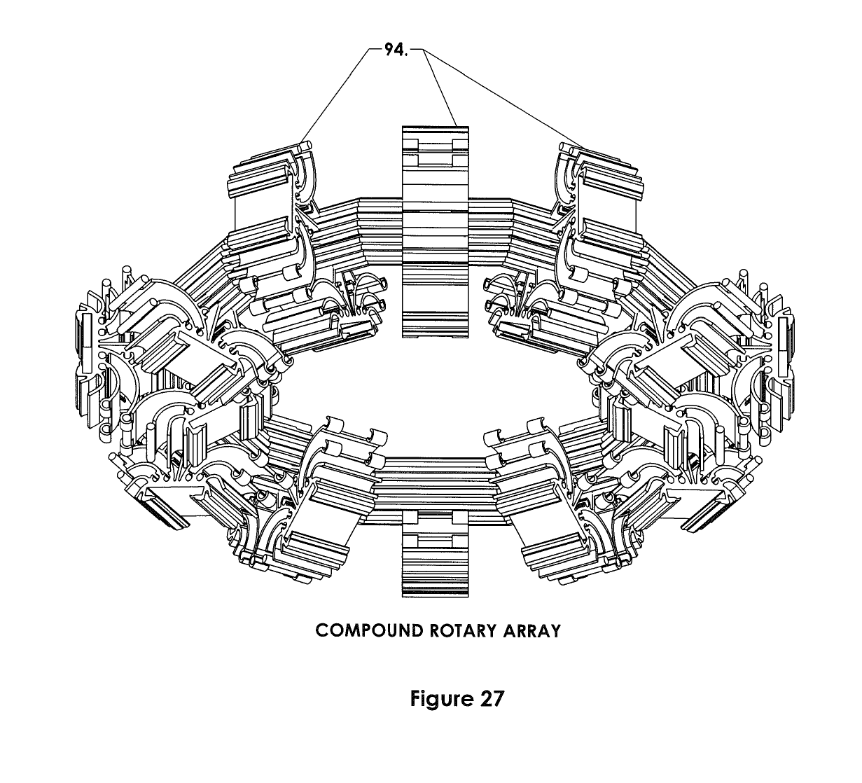

Referring to FIGS. 26-29, a preferred embodiment of the invention may be expressed by a number of heat sink petals, which may exist in a plurality of forms including those described above, linked to each other and to and around various stem sections either singularly, as depicted in FIG. 26, or in groups, as depicted FIG. 27, by their respective mechanical connector features. Each stem section, as depicted in FIG. 26, may be joined to each other stem section at their respective ends (93) to collectively form shapes that can include an equilateral convex polygon, which may be referred to as an umbel, as depicted in FIGS. 26 and 27.

An umbel may have its general horizontal exterior dimensions, its sides, defined by linked stem sections; each stem section existing in a given umbel shall generally be of an equivalent length to all other stem sections comprising the various sides of an umbel. Each stem section defining the sides of an umbel may be substantially identical to the stem as it is described in the first embodiment, at FIGS. 8 and 9. Each end of each stem may be linked respectively to the adjoining ends of each stem to its left and right by an adhering agent such as thermal epoxy or through the use of another affixation component such as threaded wire or a mechanical connector feature.

Petals may be placed on and around the exterior portions of each section of stem comprising a side of an umbel; the petals may be arranged in groups (94), as depicted in FIG. 27, or by themselves (95), as depicted in FIG. 26. In the illustrated embodiment, as depicted in FIG. 26, one petal may be linked to the bottom side of each section of stem for a total of 10 petals on 10 sides.

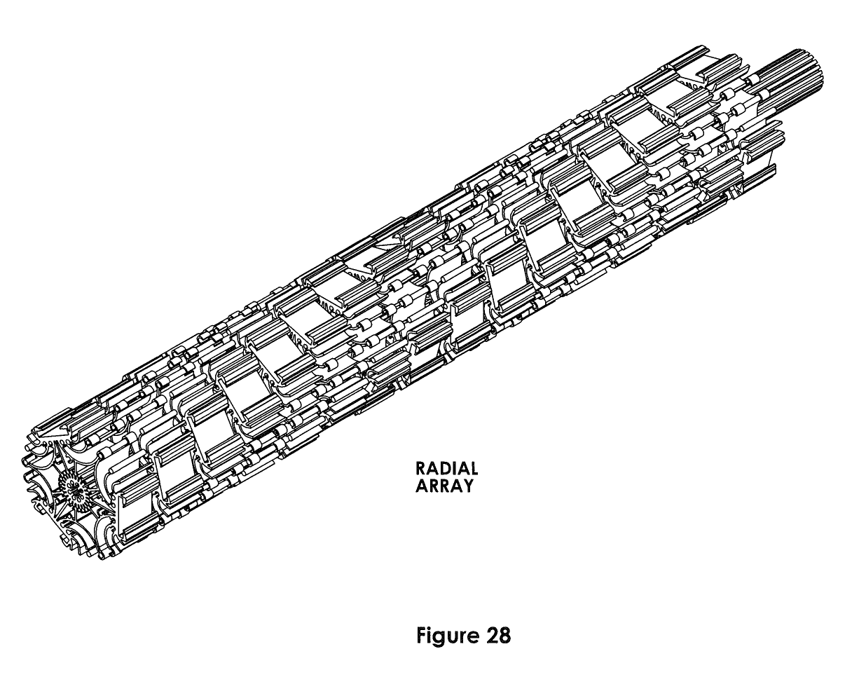

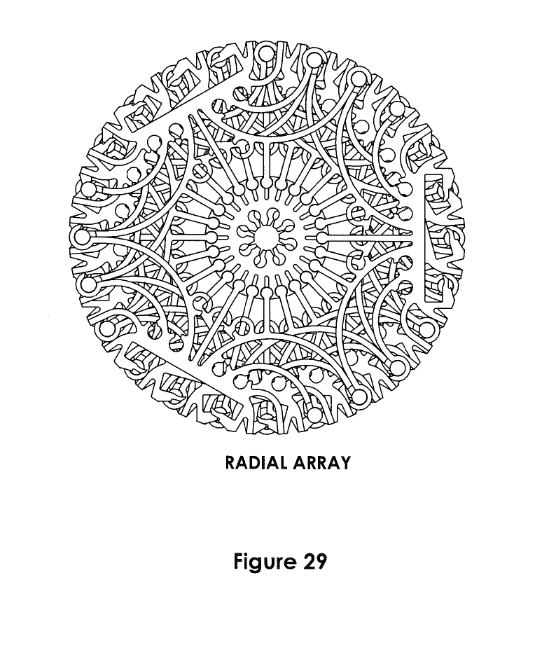

The number of petals affixed upon a given section of stem need only be limited by 15 degree increments of separation; 15 degrees being the amount by which the center axis of each elongated cylindrical claw feature extending along the outer surface area of each stem section may be spaced from each other, as depicted in FIGS. 8 and 9. Therefore, if desired, numerous petals may occupy a single stem section comprising one side of an umbel where each of the petals are placed length-side parallel to each other and staggered around and along the length of the stem section by increments of 15 degrees, forming a spiral-like appearance, as depicted in FIGS. 28 and 29.

The various manners in which petals and petal groupings may be arranged on any given section of stem comprising a side of an umbel, and the various number of stem sides which may be linked together at their respective ends to form an umbel allows a plurality of different embodiments of the invention to be conceived. A heat transfer compound such as thermal grease can be placed in the petal connectors to improve conductive heat transfer between connected petals.

The present disclosure, in various embodiments, includes components, methods, processes, systems and/or apparatus substantially as depicted and described herein, including various embodiments, subcombinations, and subsets thereof. Those of skill in the art will understand how to make and use the present disclosure after understanding the present disclosure. The present disclosure, in various embodiments, includes providing devices and processes in the absence of items not depicted and/or described herein or in various embodiments hereof, including in the absence of such items as may have been used in previous devices or processes, e.g., for improving performance, achieving ease and/or reducing cost of implementation. Rather, as the flowing claims reflect, inventive aspects lie in less than all features of any single foregoing disclosed embodiment.

What is claimed is:

1. A heat sink petal comprising:
a) a petal body having an upper side and a lower side;
b) a plurality of fins extending outward from the upper side and the lower side of the petal body for dissipating heat;
c) a mounting surface on the lower side for securing a heat producing device to the petal body;
d) a ball connector extending from a right side of the pedal body having an elongated cylindrical configuration; and
e) a claw connector extending from a left side of the pedal body having an elongated cylindrically contoured wall section with portions thereof extending over an arc of greater than 180 degrees and having an open side with portions thereof extending over an arc of less than 180 degrees.

2. The heat sink petal of claim 1 further comprising:
a fastening mechanism on the mounting surface for securing the heat producing device to the heat sink petal.

3. The heat sink petal of claim 2 wherein the heat producing device is a light emitting diode (LED).

4. The heat sink petal of claim 1 wherein the ball connector defines a ball connector axis and the claw connector defines a claw connector axis and the ball connector axis is substantially parallel to the claw connector axis.

5. The heat sink petal of claim 4 wherein a first edge of the petal body and the ball connector axis define a first plane and a second edge of the petal body and the claw connector axis define a second plane and an intersection of the first plane and the second plane defines an angle that is between about 80 degrees and 130 degrees.

6. The heat sink petal of claim 1 further comprising:
stem connectors extending from the upper side of the pedal body for attaching the heat sink petal to a stem structure.

7. A heat sink comprising:
a first heat sink petal comprising:
a) a petal body having an upper side and a lower side;
b) a plurality of fins extending outward from the upper side and the lower side of the petal body for dissipating heat;
c) a mounting surface on the lower side for securing a heat producing device to the petal body;
d) a ball connector extending from a right side of the pedal body having an elongated cylindrical configuration; and
e) a claw connector extending from a left side of the pedal body having an elongated cylindrically contoured wall section with portions thereof extending over an arc of greater than 180 degrees and having an open side with portions thereof extending over an arc of less than 180 degrees; and
a second heat sink petal which is substantially identical to the first heat sink petal;
wherein the ball connector of the first heat sink petal is coupled to the claw connector of the second heat sink petal.

8. The heat sink of claim 7 wherein the mounting surface of the first heat sink petal and the mounting surface of the second heat sink petal face opposite directions.

9. The heat sink of claim 7 further comprising:
a third heat sink petal that is substantially identical to the first heat sink petal;
wherein the ball connector of the second heat sink petal is coupled to the claw connector of the third heat sink petal.

10. The heat sink of claim 9 wherein the first heat sink petal, the second heat sink petal and the third heat sink petal each form a portion of a convex polygon.

11. The heat sink of claim 9 wherein the mounting surfaces of the first heat sink petal, the second heat sink petal and the third heat sink petal face outward from the heat sink.

12. The heat sink of claim 7 wherein a first edge of the first petal body and the ball connector define a first plane and a second edge of the first petal body and the claw connector define a second plane and an intersection of the first plane and the second plane defines an angle that is between about 80 degrees and 130 degrees.

13. The heat sink of claim 7 wherein the heat producing device is a light emitting diode (LED).

14. A heat sink comprising:
a first heat sink petal comprising:
a) a petal body having an upper side and a lower side;
b) a plurality of fins extending outward from the upper side and the lower side of the petal body for dissipating heat;
c) a mounting surface on the lower side for securing a heat producing device to the petal body;
d) a ball connector extending from a right side of the pedal body having an elongated cylindrical configuration;
e) a claw connector extending from a left side of the pedal body having an elongated cylindrically contoured wall section with portions thereof extending over an arc of greater than 180 degrees and having an open side with portions thereof extending over an arc of less than 180 degrees; and
f) a stem connector extending from the upper side of the pedal body; and
a stem having an elongated shape, the stem having a plurality of fins extending outward from the stem;
wherein the stem connector of the first heat sink petal is coupled to the stem.

15. The heat sink of claim 14 wherein the stem connector of the first heat sink petal is a stem claw connector having an elongated cylindrically contoured wall section with portions thereof extending over an arc of greater than 180 degrees and having an open side with portions thereof extending over an arc of less than 180 degrees, the stem further comprises stem ball connectors having an elongated cylindrical configuration and the stem claw connector of the first pedal is coupled to one of the stem ball connectors of the stem.

16. The heat sink of claim 14 wherein the stem connector of the first heat sink pedal is a stem ball connector having an elongated cylindrical configuration, the stern further comprises stem claw connectors, each of the stem claw connectors having an elongated cylindrically contoured wall section with portions thereof extending over an arc of greater than 180 degrees and having an open side with portions thereof extending over an arc of less than 180 degrees and the stem ball connector of the first heat sink petal is coupled to one of the stem claw connectors of the stem.

17. The heat sink of claim 14 wherein the stem is coupled to additional stems which are each coupled to additional heat sink pedals.

18. The heat sink of claim 14 wherein the stem and the additional stems form a polygon.

19. The heat sink of claim 18 wherein the polygon is an equilateral convex polygon.

20. The heat sink of claim 14 wherein the heat producing device is a light emitting diode (LED).
